(19) United States
(12) Patent Application Publication
(10) Pub. No.: US 2019/0355598 A1
(43) Pub. Date: Nov. 21, 2019

(54) PROCESSING APPARATUS, MEMBER, AND TEMPERATURE CONTROL METHOD

(71) Applicant: Tokyo Electron Limited, Tokyo (JP)

(72) Inventor: Eitaro KATAOKA, Miyagi (JP)

(21) Appl. No.: 16/406,244

(22) Filed: May 8, 2019

(30) Foreign Application Priority Data
May 15, 2018 (JP) 2018-094092

(51) Int. Cl. H01L 21/67; H01L 21/683; H01J 37/32

(52) U.S. Cl. CPC H01L 21/67109; H01J 37/3244; H01J 37/32091; H01L 21/6833

(57) ABSTRACT

A processing apparatus includes a processing container in which a processing space is formed, a member that is disposed in the processing container, and a flow path formed inside the member, wherein the flow path is provided in a plurality of stages with respect to a surface of the member on a side of the processing space.

### CROSS-REFERENCE TO RELATED APPLICATIONS

This patent application is based upon and claims priority to Japanese Patent Application No. 2018-094092 filed on May 15, 2018, the entire contents of which are incorporated herein by reference.

### TECHNICAL FIELD

The present disclosure relates to a processing apparatus, a member, and a temperature control method.

### BACKGROUND

For example, Patent Document 1 proposes a semiconductor cooling device capable of improving cooling efficiency and coolant accuracy without decreasing the flow rate of the coolant flowing in the cooling flow path, and also capable of reducing size and cost.

[Patent Document 1] Japanese Laid-open Patent Publication No. 2007-258624

### SUMMARY

According to one aspect of the present disclosure, there is provided a processing apparatus having a processing container having a processing space therein, a member disposed in the processing container, and a flow path formed in the interior of the member, wherein the flow path is provided in a plurality of stages with respect to a surface of the member on the processing space side.

### BRIEF DESCRIPTION OF THE DRAWINGS

FIG. 1 is a view showing an example of a cooling flow path of a conventional mounting table.

FIG. 2 is a vertical cross-sectional view showing an example of a plasma processing apparatus according to an embodiment.

FIG. 3 is a view showing an example of a cooling flow path of a mounting table according to the embodiment.

FIG. 4 is a view showing an example of an upper cooling flow path according to the embodiment.

FIG. 5 is a view showing an example of a lower cooling flow path according to the embodiment.

FIG. 6 is a view showing an example of a method for controlling the temperature of a coolant according to an embodiment.

### DETAILED DESCRIPTION OF EMBODIMENTS

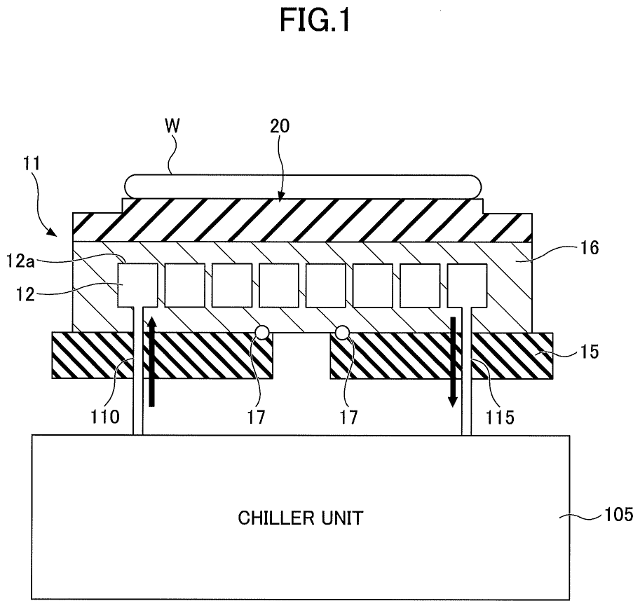

A description of embodiments of the present disclosure is given below, with reference to FIG. 1 through FIG. 6.

The embodiments described below are only examples and the present disclosure is not limited to the embodiments.

Through all figures illustrating the embodiments, the same references symbols are used for portions having the same function, and repetitive explanations of these portions are omitted.

Reference symbols typically designate as follows:
1: plasma processing apparatus;
10: processing container;
11: mounting table;
12, 13: cooling flow path;
12a, 13a: coolant pipe;
13b, 13c: valve plate;
17: O-ring;
14: heater;
40: showerhead;
40b: ceiling plate;
42, 43: cooling flow path;
42a, 43a: coolant pipe;
105: chiller unit;
106: pump; and
U: processing space.

### SUMMARY

The present disclosure provides a technique capable of adjusting a temperature distribution of a member in which a flow path is formed.

### DETAILED DESCRIPTION

### Introduction

First, an example of a cooling flow path of a conventional mounting table will be described with reference to FIG. 1.

FIG. 1 is a view showing an example of a conventional cooling flow path 12 formed in a mounting table 11. The mounting table 11 includes a base 16 and an electrostatic chuck 20. An electrostatic chuck 20 is disposed on the mounting table 11, and a wafer W is mounted on the electrostatic chuck 20.

The base 16 is made with aluminum, titanium, or the like. A coolant pipe 12a is provided inside the base 16, and the inside of coolant pipe 12a is a cooling flow passage 12. The coolant pipe 12a is connected to the coolant inlet pipe 110 and the coolant outlet pipe 115. The chiller unit 105 controls the coolant to a predetermined temperature and outputs the coolant. The coolant of a predetermined temperature output from the chiller unit 105 circulates through the path of the coolant inlet pipe 110, the coolant pipe 12a (cooling flow path 12), the coolant outlet pipe 115, and the chiller unit 105. The temperature of the mounting table 11 is controlled by the circulating coolant in this manner, whereby the temperature of the wafer W is adjusted.

When temperature control is performed only by the chiller unit 105, the O-ring 17 made of resin or the like is deformed by repeated expansion and contraction caused by temperature changes. As a result, the function of the O-ring 17 for blocking the vacuum space and the atmospheric space between the base 16 and the support member 15 for supporting the base 16 is degraded, and a problem may occur in which the vacuum space and the atmospheric space of the processing apparatus in which the mounting table 11 is placed communicate with each other. In particular, when rapid temperature control is performed by a coolant having a large temperature difference, a temperature change inside the mounting table 11 becomes large, and the above-mentioned problem easily occurs.

Therefore, the plasma processing apparatus 1, in which the mounting table 11 capable of moderating the temperature change of the portion of the base 16 in contact with the O-ring 17 is disposed, will be described. The mounting table 11 has a hierarchical flow path. [Configuration of Plasma Processing Apparatus]

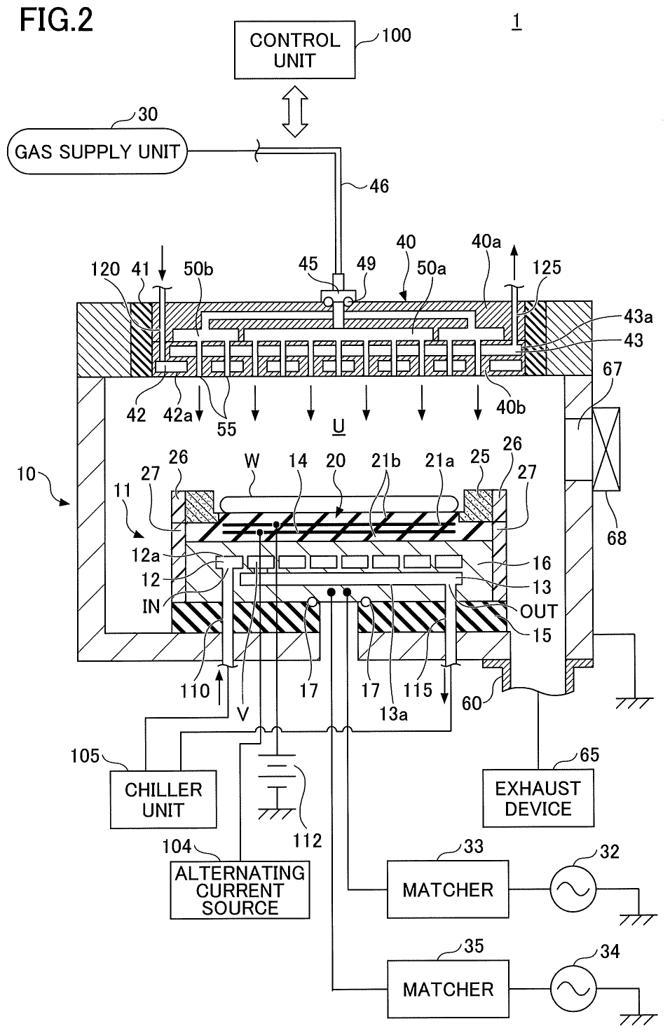

First, an example of a configuration of a plasma processing apparatus 1 according to an embodiment of the present disclosure will be described with reference to FIG. 2. FIG. 2 is a vertical cross-sectional view showing an example of the plasma processing apparatus 1 according to the embodiment. In the present embodiment, a capacitively-coupled parallel-plate plasma processing apparatus is given as an example of the plasma processing apparatus 1.

The plasma processing apparatus 1 has a cylindrical processing container 10 made of aluminum whose surface is anodized, for example. The processing container 10 is grounded. Inside the processing container 10, a mounting table 11, on which the wafer W is mounted, is provided. The mounting table 11 is installed on the bottom of the processing container 10 via an insulating support member 15. Between the base 16 and the support member 15 supporting the base 16, an O-ring 17 is provided for blocking the vacuum space from the atmospheric space.

The mounting table 11 includes a base 16 and an electrostatic chuck 20. The electrostatic chuck 20 has a structure in which an adsorption electrode 21a is interposed between insulators 21b. The adsorption electrode 21a is connected to a DC power supply 112. When a DC voltage is applied to the adsorption electrode 21a from the DC power source 112, the wafer W is electrostatically adsorbed to the electrostatic chuck 20. A heater 14 is incorporated under the adsorption electrode 21a in the insulator 21b.

The base 16 is made of a conductive metal such as aluminum (Al), titanium (Ti), or conductive silicon carbide (SiC). Inside the base 16, coolant pipes 12a and 13a forming multiple stages of cooling flow paths 12 and 13 are provided.

A coolant inlet pipe 110 is connected to the coolant pipe 12a, and a coolant outlet pipe 115 is connected to the coolant pipe 13a. The coolant inlet pipe 110 and the coolant outlet pipe 115 are connected to the chiller unit 105.

The coolant output from the chiller unit 105, for example, cooling water, galden, Fluorinert (“Fluorinert” is a registered trademark), or the like, is an example of a temperature controlled medium. The coolant is controlled to have a set temperature by the chiller unit 105, and flows into the upper cooling flow path 12 from the inlet IN of the coolant pipe 12a connected to the coolant inlet pipe 110. After flowing through the cooling flow path 12 in the base 16, the coolant flows from the outlet V of the coolant pipe 12a in the cooling flow path 13 of the coolant pipe 13a connected to the outlet V. Then, the coolant flows from the outlet OUT of the coolant pipe 13a to the coolant outlet pipe 115, and returns to the chiller unit 105. In this manner, the mounting table 11 is cooled by the coolant circulating therein. The cooling flow paths 12 and 13 may have a width equal to or greater than the diameter of the wafer W.

The heater 14 is supplied with power from an AC power source 104. As a result, the mounting table 11 is heated. The temperature of the mounting table 11 is adjusted by cooling by the coolant flowing through the cooling flow paths 12 and 13 and heating by the heater 14. When the set temperature of the heater 14 and the set temperature of the coolant of the chiller unit 105 are determined, the electric power to be applied to the heater 14 is determined. With such a configuration, the temperature of the wafer W can be controlled to be a desired temperature. Here, the heater 14 may not be provided.

An edge ring 25 made with, for example, single crystal silicon is provided on the outer peripheral side of the wafer W. Further, a hollow cover ring 26 made with, for example, quartz or the like and a cylindrical insulator ring 27 are provided so as to surround the outer peripheral surfaces of the edge ring 25 and the mounting table 11.

A high frequency power source 32 is connected to the base 16 via a matcher 33, and a high frequency power source 34 is connected via a matcher 35. The high frequency power source 32 supplies power of a high frequency HF for plasma generation at a predetermined frequency to the base 16. The high frequency power source 34 supplies the base 16 with a high frequency LF for drawing ions having a frequency lower than the frequency output from the high frequency power source 32. With this configuration, the mounting table 11 functions as a lower electrode. Although not shown, a heat transfer gas such as a helium gas may be supplied between the back surface of the wafer W and the front surface of the electrostatic chuck 20.

Above the mounting table 11, a showerhead 40, which faces the mounting table 11 and functions as an upper electrode, is provided. The space between the mounting table 11 and the showerhead 40 is a processing space U in which plasma is generated. The power of the high frequency HF for plasma generation may be applied to the upper electrode instead of being applied to the lower electrode.

The showerhead 40 has a main body 40a and a ceiling plate 40b, and is provided on the ceiling portion of the processing container 10. The showerhead 40 is supported by the processing container 10 via an insulating member 41. The main body 40a may be made with a conductive material, for example, aluminum whose surface has been anodized. The ceiling plate 40b is detachably supported by the main body 40a at a lower portion of the main body 40a.

Inside the main body 40a, a gas diffusion chamber 50a on the center side and a gas diffusion chamber 50b on the outer periphery side are provided. A large number of gas holes 55 communicating with the gas diffusion chambers 50a and 50b are formed in the ceiling plate 40b.

A gas inlet 45 for introducing a processing gas into the gas diffusion chambers 50a and 50b is formed in the main body 40a. A gas supply pipe 46 is connected to the gas inlet 45, and a gas supply unit 30 is connected to the gas supply pipe 46. A predetermined processing gas such as plasma etching is supplied from the gas supply unit 30 to the gas diffusion chambers 50 a and 50 b through the gas supply pipe 46. The processing gas diffused in the gas diffusion chambers 50 a and 50 b is dispersed and supplied in a shower shape into the processing container 10 through the gas holes 55. An O-ring 49 is provided between the member of the gas inlet 45 and the main body 40a to block the vacuum space and the atmosphere space.

Coolant pipes 42a and 43a that form cooling flow paths 42 and 43 in multiple stages are provided inside the ceiling plate 40b. A coolant inlet pipe 120 is connected to the coolant pipe 42a, and a coolant outlet pipe 125 is connected to the coolant pipe 43a. The coolant inlet pipe 120 and the coolant outlet pipe 125 are connected to the chiller unit 105. However, the chiller unit connected to the coolant pipes 42a and 43a for the coolant may be the chiller unit 105 or another chiller unit.

The coolant output from the chiller unit 105 flows from the inlet of the coolant pipe 42a connected to the coolant inlet pipe 120 into the cooling flow path 42 at the lower stage, flows through the cooling flow path 42 in the ceiling plate 40b, and then flows through the cooling flow path 43 at the upper stage of the coolant pipe 43 a connected to the exit of the coolant pipe 42a. Then, it flows out from the outlet of the coolant pipe 43 a to the coolant outlet pipe 125, and returns to the chiller unit 105. In this manner, the showerhead 40 is cooled by the coolant circulating therein.
The cooling flow paths 42 and 43 may have a width equal to or greater than the diameter of the wafer W.

An exhaust pipe 60 is formed at the bottom of the processing container 10, and an exhaust device 65 is connected to the exhaust pipe 60. The exhaust device 65 has a vacuum pump, and by operating the vacuum pump, the inside of the processing container 10 is depressurized to a predetermined degree of vacuum. A transfer-in/out port 67 for the wafer W is provided in the sidewall of the processing container 10, and a gate valve 68 for opening and closing the transfer-in/out port 67 is provided in the transfer-in/out port 67.

The plasma processing apparatus 1 is controlled by the control unit 100. The control unit 100 is provided with a CPU, a memory, and a user interface. The user interface includes a keyboard for a process manager to input commands for managing the plasma processing apparatus 1, a display for visualizing and displaying the operating state of the plasma processing apparatus 1, and the like.

The memory stores a recipe in which data relating to processing conditions such as a control program (software) to be substantialized by the control of the CPU, a set temperature of the coolant of the chiller unit, and the like are stored. The recipe of the control program, the processing condition data, or the like may be stored in a computer storage medium readable by a computer, such as a hard disk, a CD, a flexible disk, a semiconductor memory, or the like. Recipes such as a control program and processing condition data can be transmitted from another device via a dedicated line at any time and used online.

When the wafer W is transferred, the gate valve 68 is opened, and when the wafer W is transferred into the processing container 10 from the transfer-in/out port 67, the lift pins are raised, and the wafer W is transferred from the arm to the lift pins and supported by the lift pins. The lift pin moves up and down by driving a motor or the like. When the lift pins are lowered and the wafer W is mounted on the mounting table 11, a DC voltage is applied to the adsorption electrode 21a from the DC power source 112, and the wafer W is adsorbed and held by the electrostatic chuck 20.

In addition, the processing gas is supplied from the gas supply unit 30 into the processing container 10, and the power of the high-frequency HF for plasma generation is applied from the high frequency power source 32 to the mounting table 11. The high frequency power source 34 may apply the power of the high-frequency LF for ion drawing to the mounting table 11.

As a result, plasma processing, for example, etching, is performed on the wafer W by the action of the plasma generated above the wafer W and ion attraction.

In the plasma processing apparatus 1 according to the present embodiment, a plurality of stages of cooling flow paths are formed in the mounting table 11 and the showerhead 40. In any of the members, the coolant output from the chiller unit 105 directly enters the flow path on the side closer to the processing space U, exits the flow path on the side farther from the processing space U, and returns to the chiller unit 105.

The mounting table 11 and the showerhead 40 are members arranged in the processing container 10, and are examples of members in which multiple stages of cooling flow paths are provided and whose temperature is controlled by a temperature controlled medium. The member for providing the cooling flow paths of the multiple stages is not limited to the mounting table 11 or the showerhead 40, and may be any member used for the plasma processing apparatus 1.

### [Cooling Flow Path]

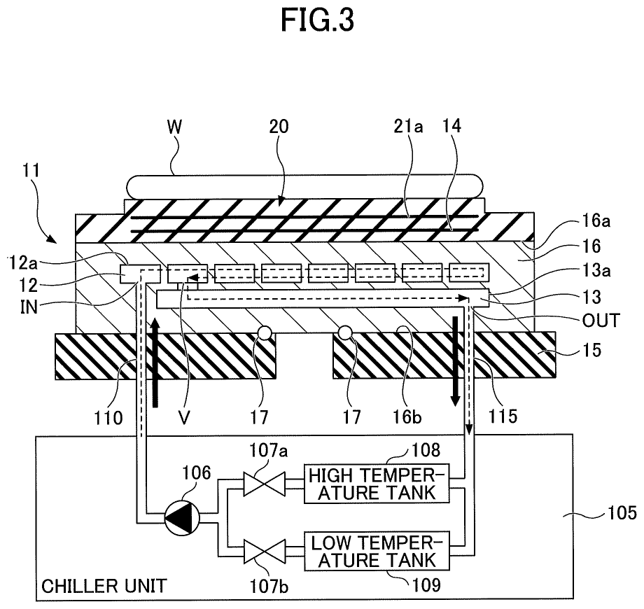

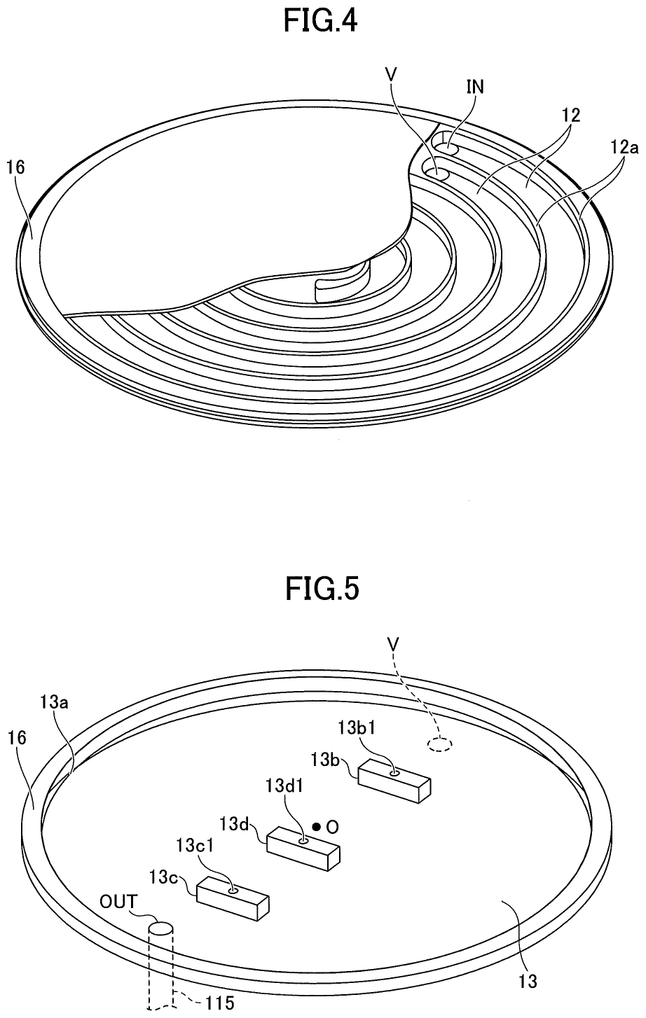

Next, an example of the cooling flow path in the mounting table 11 according to the embodiment will be described in detail with reference to FIGS. 3 to 5. FIG. 3 is a view showing an example of a cooling mechanism including the cooling flow paths 12 and 13 of the mounting table 11 according to the embodiment. FIG. 4 is a view showing an example of the upper cooling flow path 12 according to the embodiment. FIG. 5 is a view showing an example of the lower cooling flow path 13 according to the embodiment.

The cooling flow paths 12 and 13 formed in the coolant pipes 12a and 13a are provided in a plurality of stages in a direction perpendicular to the surface of the base 16 of the mounting table 11 on the side of the processing space U. The coolant flows in from the cooling flow path 12 on the side close to the surface of the base 16 on the side of the processing space U of the cooling flow paths 12 and 13, and flows out from the cooling flow path 13 on the side far from the surface of the base 16 on the side of the processing space U side.

Specifically, the coolant is controlled to a set temperature by the chiller unit 105. The chiller unit 105 includes a pump 106, a high temperature tank 108, a low temperature tank 109, a valve body 107a, and a valve body 107b.

In the high temperature tank 108, the temperature of the coolant is controlled to be a first temperature (e.g., 90° C.). In the low temperature tank 109, the temperature of the coolant is controlled to be a second temperature (e.g., 10° C.) lower than the first temperature.

By switching to open and close the valve bodies 107a and 107b, the coolant in the high temperature tank 108 and the low temperature tank 109 respectively flows to the pump 106. When the valve body 107a is opened and the valve body 107b is closed, the coolant of the first temperature is supplied from the high temperature tank 108 to the pump 106. When the valve body 107b is opened and the valve body 107a is closed, the coolant of the second temperature is supplied from the low temperature tank 109 to the pump 106.

The pump 106 controls the flow rate of the coolant to be output by changing the operating frequency by the inverter. The coolant output from the pump 106 flows into the upper cooling flow path 12 from the inlet IN of the coolant pipe 12a connected to the coolant inlet pipe 110. After flowing through the cooling flow path 12, the coolant enters the cooling flow path 13 of the coolant pipe 13 a connected from the exit V to the outlet V of the coolant pipe 12a. Then, the coolant flows out from the outlet OUT of the coolant pipe 13a to the coolant outlet pipe 115, returns to the high temperature tank 108 and the low temperature tank 109 in the chiller unit 105, and is controlled to each set temperature. In this manner, the temperatures of the mounting table 11 and the wafer W are adjusted.

A resin O-ring 17 is provided between the base 16 and the insulating support member 15 on the surface 16b opposite to the surface 16a on the side of the processing space U. When the temperature of the coolant controlled by the chiller unit 105 has a temperature difference of, for example, 10° C. and 90° C., and a temperature control is suddenly performed on the mounting table 11, a temperature change suddenly occurs on the mounting table 11. The O-ring 17 is deformed by repeated expansion and contraction due to this sudden temperature change.

On the other hand, in the cooling flow paths 12 and 13 of the multiple stages according to the present embodiment, the coolant output from the chiller unit 105 directly enters the cooling flow path 12 on the side closer to the processing space U, and exits from the cooling flow path 13 on the side farther from the processing space U.

According to this, in a state where the temperature change of the base 16 between the upper surface 16a of the base 16 and the upper cooling flow path 12 is large, the temperature change of the base 16 between the lower surface 16b of the base 16 and the lower cooling flow path 13 can be made moderate (the amount of temperature change is made small). This makes it possible to suppress the deformation of the O-ring 17 while ensuring the controllability of the temperature of the wafer W.

The configuration of the cooling flow paths 12 and 13 will be described with reference to FIGS. 4 and 5. As shown in FIG. 4, the upper cooling flow path 12 provided in the base 16 is formed by a spiral-shaped coolant pipe 12a. The upper cooling flow path 12 may be formed in a concentric ring shape. The width of the cooling flow path 12 may be, for example, about 10 mm to 15 mm. The height of the cooling flow path 12 is not fixed, but may be designed according to the width of the cooling flow path 12.

At the end of the cooling flow path 12, a hole of an inlet IN connected to the coolant inlet pipe 110 and a hole of an outlet V connected to the cooling flow path 13 are formed. The coolant supplied from the chiller unit 105 flows in from the hole of the inlet IN, flows in the spiral cooling flow path 12 clockwise inward, changes the direction of flow at the central, flows in the counterclockwise outward, and flows out from the hole of the exit V to the cooling flow path 13.

With this configuration, the coolant flowing through the cooling flow path 12 flows from the exit V into the cooling flow path 13 as indicated by the broken line arrow in FIG. 3.

As shown in FIG. 5, the cooling flow path 13 at the lower stage is hollow. It is preferable that the inlet of the coolant provided in the cooling flow path 13 (a portion of the cooling flow path 13 communicating with the outlet V) and the outlet OUT be provided at a position substantially symmetrical with respect to the center point O of the disk-shaped cooling flow path 13 and at or near the outer edge of the cooling flow path 13. Thus, by lengthening the time during which the coolant stays in the cooling flow path 13, the temperature change of the base 16 between the lower surface 16b of the base 16 and the cooling flow path 13 can be made gradual, and the deformation of the ring 17 can be suppressed.

In addition, a member for deflecting the flow of the coolant in the cooling flow path 13 may be provided. For example, in the example of FIG. 5, the valve plates 13b and 13c are provided in the cooling flow path 13. The valve plates 13b, 13c, and 13d are provided so as to be rotatable about the rotation shafts 13b1, 13c1, and 13d1. As a result, the coolant stays for a longer time, and the temperature of the coolant in the cooling flow path 13 is made more uniform, so that the temperature change of the base 16 between the lower surface 16b of the base 16 and the cooling flow path 13 can be made more moderate. This makes it possible to efficiently suppress deformation of the O-ring 17.

The number of the valve plates 13b, 13c, and 13d may not be three, and may be one or more. Further, the present disclosure is not limited to the rotating valve plate, and any member may be used as long as it inhibits the flow of the coolant. It is preferable to dispose a member for inhibiting the flow of the coolant between a line connecting the inlet of the coolant (a portion of the cooling flow path 13 communicating with the outlet V) and the outlet OUT, because the flow of the coolant can be effectively inhibited.

The member for deflecting the flow of the coolant in the cooling flow path 13 is not limited to the valve plate, and may have various shapes. For example, the member for deflecting the flow of the coolant in the cooling flow path 13 may be a rod-shaped member, or may be a member capable of deflecting the flow of the coolant.

As described above, according to the mounting table 11 of the present embodiment, the cooling flow paths 12 and 13 have multiple stages, and the cooling flow path 12 on the side close to the processing space U is formed in a spiral shape. This makes it possible to quickly change the temperature of the base 16 between the upper surface 16a of the base 16 and the cooling flow path 12, thereby improving the controllability of the temperature of the wafer W.

In addition, the cooling flow path 13 is made hollow, and the coolant flowing in from the cooling flow path 12 is allowed to stay for a longer time by using a member or other structure that inhibits the flow of the coolant, thereby making the temperature of the coolant in the cooling flow path 13 more uniform.

For example, a groove such as the cooling flow path 12 may be formed in the cooling flow path 13, but in this case, since friction between the cooling flow path 13 and the coolant increases, it is necessary to increase the extrusion pressure of the chiller unit 105. Therefore, it is more preferable that the inside of the cooling flow path 13 is hollow.

As an example of the effect of using the mounting table 11 having the cooling flow paths 12 and 13 having such a configuration, it is possible to reduce the temperature difference between the coolant of two set temperatures controlled by the chiller unit 105 with respect to the temperature change of the base 16 between the lower surface 16b of the base 16 and the cooling flow path 13.

For example, when the first temperature and the second temperature of the coolant controlled by the chiller unit 105 are 10° C. and 90° C., the temperature of the base 16 between the lower surface 16b of the base 16 and the cooling flow path 13 of the lower stage can be gradually changed to about 30° C., which is about ⅓ of the temperature change of 80° C.

In the above description, the configuration of the cooling flow paths 12 and 13 has been described taking the mounting table 11 as an example, but the cooling flow paths 42 and 43 formed in the showerhead 40 also function in the same manner. That is, the cooling flow paths 12 and 42 are examples of the first flow paths on the side close to the surface on the processing space U side of the member, and the cooling flow paths 13 and 43 are examples of the second flow paths on the side close to the surface on the processing space U side of the member. The cooling flow path 42 at the lower stage is preferably formed in a spiral shape or a ring shape, for example. The upper cooling flow path 43 is preferably formed to be hollow.

When the showerhead 40 having the cooling flow paths 42 and 43 having such a configuration is used, the showerhead 40 on the processing space U side in which plasma is generated by the cooling flow path 42 can be quickly cooled. In addition, the temperature change of the ceiling plate 40b between the upper surface of the ceiling plate 40b and the cooling flow path 43 can be made gradual. For example, the temperature difference between the coolant at the first temperature and the coolant at the second temperature can be about ⅓. As a result, it is possible to suppress the O-ring 49 from being deformed by repeated expansion and contraction due to temperature change.

The cooling flow paths of a plurality of stages provided in the members such as the mounting table 11 and the showerhead 40 are not limited to two stages, and may be three or more stages. In this case, the cooling flow path of the center stage may be formed in a spiral shape or a concentric circle shape, or may be formed in a hollow shape, depending on the position and size thereof.

### [Temperature Control Method]

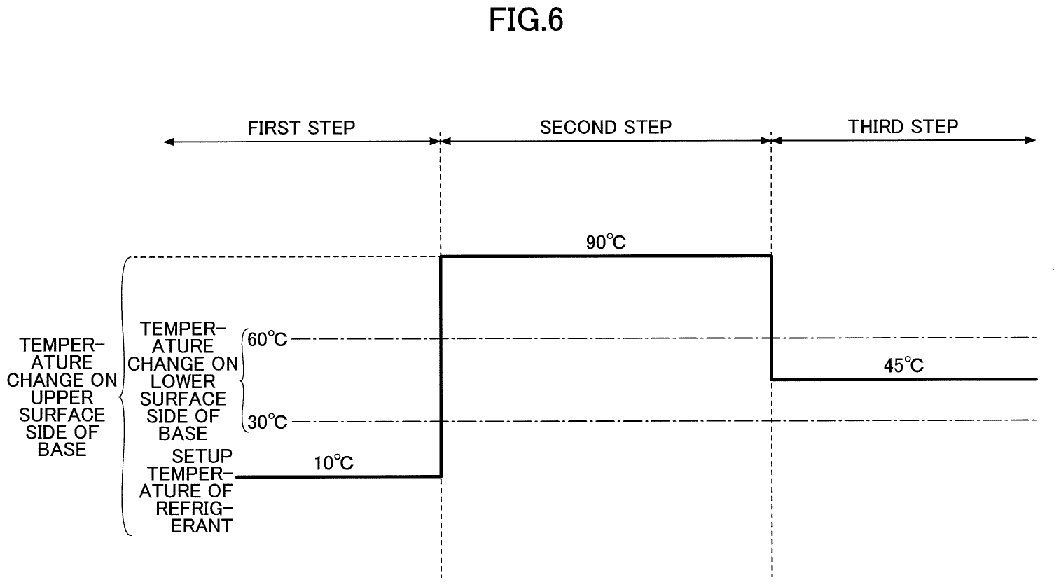

Finally, an example of a temperature control method according to an embodiment executed in the plasma processing apparatus 1 will be described with reference to FIG. 6. In the following, the temperature adjustment of the mounting table 11 is controlled by the coolant of the first temperature and the coolant of the second temperature flowing through the cooling flow paths 12 and 13, and the adjustment by the heating of the heater 14 is omitted.

In the temperature control method according to the embodiment, a first film is formed in a first step, a second film is formed in a second step, and a third film is formed in a third step. The set temperature of the chiller unit 105 is set. The pump 106 sends the coolant at 10° C. to the cooling flow path 12 on the side close to the surface a on the processing space U side of the mounting table 11, and executes the first step of causing the coolant to flow out from the cooling flow path 13 on the side far from the surface 16a on the processing space U side.

Next, in the second step, the valve body 107a of the chiller unit 105 is opened and the valve body 107b is closed. As a result, the coolant set at 90° C. is supplied from the high temperature tank 108 to the pump 106. The pump 106 executes the second step of causing the coolant at 90° C. to flow in from the cooling flow path 12 on the side close to the surface on the processing space U side of the mounting table 11, and to flow out from the cooling flow path 13 on the side far from the surface on the processing space U side.

Next, in a third step, the valve bodies 107a and 107b of the chiller unit 105 are opened to a medium degree. As a result, the coolant set at 90° C. and 10° C. is respectively supplied from the high temperature tank 108 and the low temperature tank 109 to the pump 106. Then, the third step is performed in which the coolant set at 45° C. flows in from the cooling flow path 12 on the side close to the surface on the processing space U side of the mounting table 11, and flows out from the cooling flow path 13 on the side far from the surface on the side of the processing space U.

This also makes it possible to moderately change the temperature change of the base 16 between the lower surface 16b of the base 16 and the cooling flow path 13 by about ⅓ of the maximum temperature difference controlled by the chiller unit 105, here about 30° C. of about ⅓ of the maximum temperature difference of 80° C.

The processing apparatus, components, and temperature control method according to the embodiment disclosed herein are to be considered in all respects as illustrative and not restrictive. The embodiments described above may be modified and improved in various forms without departing from the scope and spirit of the appended claims. The items described in the plurality of embodiments may be configured in other manners to the extent that they do not conflict with each other, and may be combined to the extent that they do not conflict with each other.

The disclosed processing apparatus is applicable to any of the following types: Capacitively Coupled Plasma (CCP), Inductively Coupled Plasma (ICP), Radial Line Slot Antenna, Electron Cyclotron Resonance Plasma (ECR), and Helicon Wave Plasma (HWP).

In the present specification, the wafer W has been described as an example of the substrate However, the substrate is not limited to this, and may be any of various substrates, printed circuit boards, and the like used for FPDs (Flat Panel Display).

All examples and conditional language recited herein are intended for pedagogical purposes to aid the reader in understanding the embodiments and the concepts contributed by the inventor to furthering the art, and are to be construed as being without limitation to such specifically recited examples and conditions, nor does the organization of such examples in the specification relate to a showing of superiority or inferiority of the embodiments.

Although the processing apparatus has been described in detail, it should be understood that the various changes, substitutions, and alterations could be made hereto without departing from the spirit and scope of the disclosure.

What is claimed is:

1. A processing apparatus comprising:
a processing container 10 in which a processing space is formed;
a member that is disposed in the processing container; and
a flow path formed inside the member,
wherein the flow path is provided in a plurality of stages with respect to a surface of the member on a side of the processing space.

2. The processing apparatus according to claim 1,
wherein a temperature controlled medium flowing through the flow path flows in from a first flow path positioned on a side close to a surface on the processing space side of the member, and flows out from a second flow path positioned on a side far from the surface on the processing space side of the member.

3. The processing apparatus according to claim 1,
wherein the first flow path is formed in a spiral-like shape or a ring-like shape.

4. The processing apparatus according to claim 2,
wherein the second flow path is formed to be hollow.

5. The processing apparatus according to claim 4,
wherein an inlet and an outlet of the temperature controlled medium provided in the second flow path are respectively positioned at points symmetrical about a central axis of the second flow path and at or near the outer edge of the flow path.

6. The processing apparatus according to claim 2,
wherein a member for deflecting a flow of the temperature controlled medium is provided inside the second flow path.

7. The processing apparatus according to claim 6,
wherein the member for deflecting the flow of the temperature controlled medium is at least one valve plate or at least one rod-shaped member.

8. The processing apparatus according to claim 6,
wherein the member for deflecting the flow of the temperature controlled medium is at least one valve plate configured to be rotatable about a rotation shaft.

9. The processing apparatus according to claim 6,
wherein the member for deflecting the flow of the temperature controlled medium is disposed at a line formed between an inlet and an outlet in the second flow path.

10. The processing apparatus according to claim 2, the processing apparatus further comprising:
an O-ring in contact with a surface opposite to the surface of the processing space of the member.

11. A member disposed toward a processing space of
a processing container,
the member comprising:
a flow path that is formed in the member, the flow path being provided in a stages with respect to a surface of the member on aside of the processing space.

12. The member according to claim 11, the member comprising:
an inlet into which a temperature controlled medium flows, the inlet being provided in a first flow path on a side close to a surface on a side of a processing space of the member among the flow paths of each of the plurality of stages; and
an outlet from which the temperature controlled medium flows, the outlet being provided in a second flow path on a side far from the surface on the side of the processing space of the member.

13. The member according to claim 11,
wherein the member is a mounting table or a shower head.

14. A temperature control method for controlling a processing apparatus including
a processing container, in which a processing space is formed,
a member disposed in the processing container,
a flow path formed inside the member, the flow path being provided in a plurality of stages with respect to the surface of the member on side of the processing space, and
an O-ring in contact with a surface of the member opposite the surface of the processing space, the temperature control method comprising:
a first step, in which a temperature controlled medium having a first temperature is caused to flow in from a first flow path on a side close to the surface of the member on the side of the processing space and to flow out from a second flow path on a side far from the surface of the member on the side of the processing space; and
a second step, in which the temperature controlled medium having a second temperature different from the first temperature is caused to flow in from the first flow path and to flow out from the second flow path.

15. The temperature control method according to claim 14, the temperature control method further comprising:
a third step, in which the temperature controlled medium having the first temperature is caused to flow in from the first flow path on the side close to the surface of the member on the side of the processing space and to flow out from the second flow path on the side far from the surface of the member on the side of the processing space, and simultaneously the temperature controlled medium having the second temperature different from the first temperature is caused to flow in from the first flow path and to flow out from the second flow path.
